(19) United States
(12) Patent Application Publication
(10) Pub. No.: US 2007/0194339 A1
(43) Pub. Date: Aug. 23, 2007

(54) Optical data communication module

(75) Inventor: Tomoharu Horio, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto (JP)

(21) Appl. No.: 10/584,116

(22) PCT Filed: Dec. 21, 2004
(86) PCT No.: PCT/JP04/19090

§ 371 Date: Jun. 23, 2006

(30) Foreign Application Priority Data
Dec. 25, 2003 (JP) 2003-429322

(51) Int. Cl. H01L 33/00

(52) U.S. Cl. 257/99

(57) ABSTRACT

Disclosed is an infrared data communication module (1) comprising an infrared light-emitting device (3), an infrared light-receiving device (4) and an IC chip (5). The light-emitting device (3), light-receiving device (4) and IC chip (5) are mounted on a substrate (2) and covered with a sealing resin package (6). The substrate (2) is provided with a recessed portion (22) whose innner surface is covered with a ground-connected metal film (7), and the light-emitting device (3) is arranged in the recessed portion (22).

### TECHNICAL FIELD

The present invention relates to an optical data communication module incorporated in a personal computer, peripheral devices of the personal computer, or a mobile phone. The present invention specifically relates to an infrared data communication module.

### BACKGROUND ART

An example of a conventional infrared data communication module is illustrated in FIG. 4. The illustrated infrared data communication module 9 includes a base board 90. A light emitting element 92, a light receiving element 93, and an IC chip 94 are mounted on an upper surface 90a of the base board 90, and these components are covered by a sealing resin package 91. The resin package 91 is provided with a first lens 91a for collecting infrared rays emitted from the light emitting element 92 to improve the directivity of the infrared rays, and a second lens 91b for collecting the infrared rays entering from outside to the light receiving element 93 to improve the sensitivity. The IC chip 94 performs drive control of the light emitting element 92, and signal processing for outputting a predetermined signal based on a signal from the light receiving element 93. Such infrared data communication module is disclosed in JP-A-2002-76427 (the following patent document 1), for example.

Patent Document 1: JP-A-2002-76427

When the light emitting element 92 is driven in the infrared data communication module 9, the light emitting element 92 may generate electromagnetic noise. In the vicinity of the light emitting element 92, the IC chip 94 is provided. Thus, conventionally, the electromagnetic noise generated from the light emitting element 92 may adversely affect the IC chip 94, so that an error occurs at the IC chip 94.

Generally, for saving electrical power of the infrared data communication module and for improving its communication performance, it is required to increase the amount of infrared rays traveling in a predetermined proper direction from the light emitting element. However, in the infrared data communication module 9, the infrared rays emitted from the side surfaces of the light emitting element 92 do not travel toward the lens 91a, but travel around the light emitting element 92, in vain. In this point, there is also room for improvement.

### DISCLOSURE OF THE INVENTION

The present invention has been proposed under the above-described circumstances. It is therefore an object of the present invention to provide an optical data communication module, especially an infrared data communication module, capable of reducing possibility of error at an IC chip due to electromagnetic noise generated from a light emitting element, and of reducing the amount of infrared rays scattered about the light emitting element.

An optical data communication module according to the present invention comprises a base board, a light emitting element, a light receiving element, an IC chip and a sealing resin package. The light emitting element, the light receiving element, and the IC chip are mounted on the base board, and are covered by the sealing resin package. The base board is formed with a recess including an inner surface covered by a metal film which is grounded, and the recess accommodates the light emitting element.

Due to the structure, as the grounded metal film serves as an electromagnetic shield, electromagnetic noise generated from the light emitting element is blocked off by the metal film before arriving at the IC chip. This can prevent the error at the IC chip due to the electromagnetic noise generated from the light receiving element. Further, as the light emitted from the light emitting element is reflected at the metal film in a predetermined direction, the light can be prevented from being scattered around the light emitting element. In this way, the structure enables increase in the amount of the light emitted from the light emitting element in the predetermined direction out of the resin package, save on electrical power, and improvement in communication performance.

Preferably, the light emitting element is an infrared rays emitting element, while the light receiving element is an infrared rays receiving element.

Preferably, top surface of the metal film is higher than top of the light emitting element. Due to the structure, the electromagnetic noise is prevented from traveling from the light emitting element toward the IC chip.

Preferably, the recess is filled with a resin having elastic coefficient lower than the resin package, the resin covering the light emitting element. Due to the structure, the light emitting element is prevented from directly receiving stress from the resin package.

Preferably, the recess is an inverted trapezoidal cone having diameter that becomes smaller as proceeding toward bottom surface of the cone. Due to the structure, the infrared rays emitted around from the light emitting element can be efficiently reflected upwardly (opposite to the bottom surface) of the recess, thereby increasing the amount of the light emitted outside and improving the directivity of the light.

### BRIEF DESCRIPTION OF THE DRAWINGS

FIG. 1 is a schematic perspective view illustrating an example of an infrared data communication module according to the present invention.

FIG. 2 is a sectional view taken along lines II-II of FIG. 1.

FIG. 3 is an enlarged sectional view illustrating the principal portion of the infrared data communication module of FIG. 2.

FIG. 4 is a sectional view illustrating an example of a conventional infrared data communication module.

### BEST MODE FOR CARRYING OUT THE INVENTION

A preferred embodiment of the present invention is specifically described below with reference to the accompanying drawings.

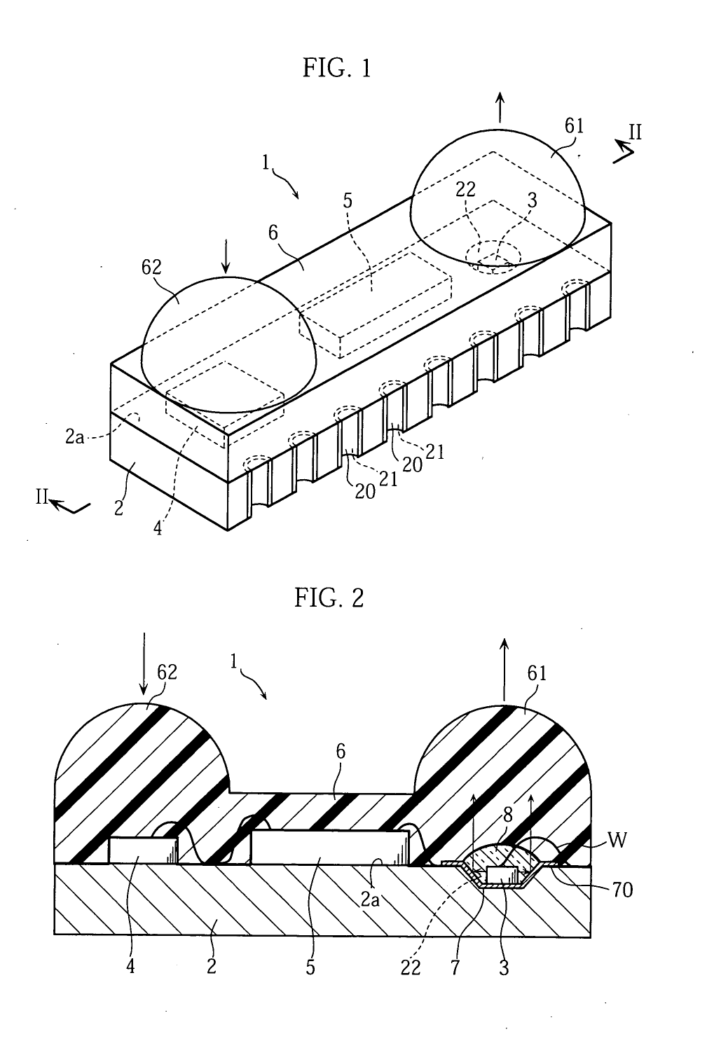

An infrared data communication module 1 illustrated in FIGS. 1 and 2 includes a base board 2, a light emitting element 3 for emitting infrared rays, a light receiving element 4 capable of sensing and receiving infrared rays, an IC chip 5, and a sealing resin package 6. The light emitting element 3, the light receiving element 4, and the IC chip 5 are mounted on an upper surface 2a of the base board 2. The sealing resin package 6 covers the light emitting element 3, the light receiving element 4, and the IC chip 5.

The base board 2 is an insulating base board made of e.g. glass epoxy resin, and is rectangular in plane. The upper surface 2a of the base board 2 is formed with a wiring pattern (not shown) for power supply as well as input and output of signal relative to the light emitting element 3, the light receiving element 4, and the IC chip 5. The lower surface of the base board 2 is formed with a plurality of terminals (not shown) for surface mounting. The terminals are connected to the wiring pattern on the upper surface 2a via a plurality of film conductors 20 formed on side surfaces of the baseboard 2. Each of the film conductors 20 is provided in a semi-cylindrical recess 21, and thus the film conductors 20 do not protrude from the side surfaces of the base board 2.

The upper surface 2a of the base board 2 is formed with a recess 22 having an opening at the top, and the light emitting element 3 is positioned within the recess 22. The recess 22 is an inverted trapezoidal cone having diameter that becomes smaller as proceeding toward the bottom of the cone, which can be formed in a machine work. A metal layer 7 is formed to entirely cover the bottom surface and the circumferential inner surface of the recess 22. The metal layer 7 includes a flange 70 covering the circumference of the recess 22.

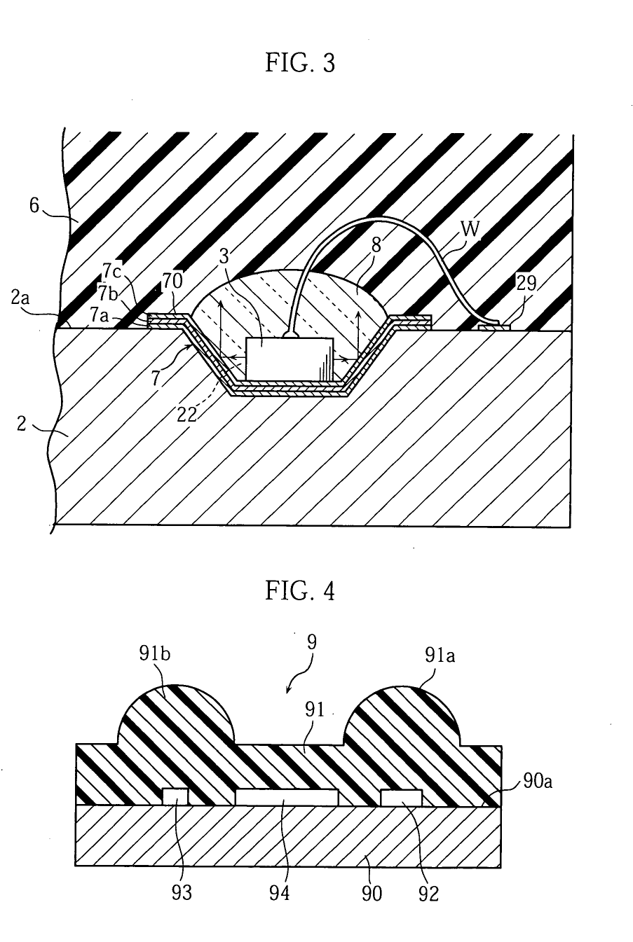

As well shown in FIG. 3, the metal layer 7 includes a plurality of films 7a-7c. The bottom most film 7a is made of e.g. copper, and formed simultaneously with the wiring pattern. The bottom most film 7a is grounded. The intermediate film 7b is made of e.g. nickel, and strengthens the bonding between the bottom most film 7a and the uppermost film (surface film) 7c. The uppermost film 7c is made of a corrosion-resistant material such as gold.

In the illustrated embodiment, the light emitting element 3 is an infrared LED bonded to the metal layer 7 by a conductive adhesive, and thus the under surface of the light emitting element 3 is provided with a cathode connected to the metal layer 7. The upper surface of the light emitting element 3 is provided with an anode connected to a pad 29 of the wiring pattern via a wire W. The top of the light emitting element 3 is lower than the upper surface of the flange 70 of the metal layer 7, so that the light emitting element 3 does not protrude beyond the opening of the recess 22. The recess 22 is provided with a buffer 8 formed by filling e.g. soft silicone resin having elasticity (elastic coefficient) lower than the sealing resin package 6. The light emitting element 3 is covered by the buffer 8. The buffer 8 has infrared permeability.

The light receiving element 4 includes a photodiode capable of sensing infrared rays. The IC chip 5 drives the light emitting element 3, and amplifies signals outputted from the light receiving element 4. The sealing resin package 6 is made of e.g. epoxy resin containing pigment, and is visible-light-impermeable but infrared-permeable. The sealing resin package 6 is provided with a first lens 61 for collecting infrared rays traveling upward from the light emitting element 3, and a second lens 62 for collecting infrared rays entering from outside onto the light receiving element 4.

In the infrared data communication module 1 of the present embodiment, as the light emitting element 3 is surrounded by the grounded metal layer 7, electromagnetic noise generated from the light emitting element 3 is blocked off by the metal layer 7. Thus, the electromagnetic noise is prevented from arriving at the IC chip 5, thereby preventing error at the IC chip 5 due to the electromagnetic noise. Especially, as the light emitting element 3 does not protrude out of the recess 22, the electromagnetic noise traveling from the light emitting element 3 to the IC chip 5 can be reliably prevented.

The infrared rays are emitted not only from the upper surface of the light emitting element 3, but also from the side surfaces of the light emitting element 3. The infrared rays emitted from the side surfaces are upwardly reflected by the surface of the metal layer 7. This structure increases the amount of the infrared rays passing through the first lens 61 of the sealing resin package 6 to be emitted upwardly. Further, as the recess 22 is an inverted trapezoidal cone having diameter that becomes smaller as proceeding toward the bottom of the cone, the infrared rays efficiently travel toward the lens 61, and the directivity of the infrared rays can be improved. Still further, the upper most film 7c of the metal layer 7 is made of gold having high reflectivity against the infrared rays, which is suitable to increase the amount of infrared rays to be emitted upwardly.

The buffer 8 prevents the light emitting element 3 from directly receiving stress from the sealing resin package 6, and also reduces the stress. Thus, the light emitting element 3 can be protected. The buffer 8 is formed by filling a material into the recess 22 in the manufacturing process of the infrared data communication module 1. When a resin in the liquid state for forming the buffer 8 is dropped over the light emitting element 3, the resin is held within the recess 22, without being spread over a large area of the base board 2.

The structure of the optical data communication module according to the present invention is not limited to the above-described embodiment, but may be modified in various ways. For example, the metal layer 7 may not include three films as described above, but may include a different number of metal films, or may be a single layer. Further, the material of the metal film of the metal layer 7 is not limited. Still further, the form and the size of the recess 22 accommodating the light emitting element 3 is not limited.

1. An optical data communication module comprising:
a base board;
a light emitting element;
a light receiving element;
an IC chip; and
a sealing resin package,
wherein the light emitting element, the light receiving element, and the IC chip are mounted on the base board, and are covered by the sealing resin package,
wherein the base board is formed with a recess including an inner surface covered by a metal film which is grounded, the recess accommodating the light emitting element.

2. The optical data communication module according to claim 1, wherein the light emitting element is an infrared rays emitting element, while the light receiving element is an infrared rays receiving element.

3. The optical data communication module according to claim 1, wherein top surface of the metal film is higher than top of the light emitting element.

4. The optical data communication module according to claim 1, wherein the recess is filled with a resin having elastic coefficient lower than the resin package, the resin covering the light emitting element.

5. The optical data communication module according to claim 1, wherein the recess is an inverted trapezoidal cone having diameter that becomes smaller as proceeding toward bottom surface of the cone.
